(19) United States
(12) Patent Application Publication
(10) Pub. No.: US 2024/0217527 A1
(43) Pub. Date: Jul. 4, 2024

(54) METHOD FOR SELF-DIAGNOSIS OF A VEHICLE SYSTEM

(71) Applicant: Robert Bosch GmbH, Stuttgart (DE)

(72) Inventors: Carsten List, Walheim (DE); David Voigt, Benningen Am Neckar (DE); Eugen Wang, Illingen (DE); Kevin Haist, Stuttgart (DE); Martin Neuberger, Remseck Am Neckar (DE); Rainer Gschwind-Schilling, Rutesheim (DE)

(21) Appl. No.: 18/557,642

(22) PCT Filed: Apr. 25, 2022
(86) PCT No.: PCT/EP2022/060924

§ 371 Date: Dec. 22, 2023

(30) Foreign Application Priority Data
Apr. 30, 2021 (DE) 10 2021 204 361.5

(51) Int. Cl. B60W 50/02; B60W 50/04

(52) U.S. Cl. CPC B60W 50/0205; B60W 50/04; B60W 2050/021; B60W 2050/0215; B60W 2050/041; B60W 2510/244

(57) ABSTRACT

A method for the self-diagnosis of a vehicle system that is supplied with energy by an on-board vehicle electrical system and includes a control unit with at least one integrated system circuit, which includes at least one internal energy supply, a sequence and logic controller and a safety controller, and with at least one microcontroller, and a vehicle system for carrying out the method.

### FIELD

The present invention relates to a method for the self-diagnosis of a vehicle system. The subject matter of the present invention is also a vehicle system configured to perform such a method.

### BACKGROUND INFORMATION

Methods for the self-diagnosis of a vehicle system as well as corresponding vehicle systems for carrying out such a method are described in the related art. Such a method for self-diagnosis can ensure that complex electronic circuits function faultlessly during their entire service life of, for example, 15 years. Here, main functions and/or properties of the vehicle system can be checked by self-diagnosis functions either once per energization cycle or continuously and/or cyclically, depending on the safety rating. A majority of these self-diagnosis functions, also referred to as BISTs (build-in self-tests), can be performed initially at every start of the vehicle system and can signal the error-free state or the failure of the diagnosis to the user. In airbag systems, this is typically indicated by an airbag warning indicator in the instrument cluster of the vehicle. It lights up at every system start and is only deactivated after the self-diagnosis has been passed successfully. Depending on the system variant, vehicle type, etc., this can take+ several seconds. Operational readiness is guaranteed only when the warning indicator is extinguished. Since the individual self-diagnosis functions for checking hardware and software almost always run sequentially, the initial scope of the diagnosis results in a substantial contribution to the time required for the initialization and/or the startup of the airbag system. Furthermore, the complexity of the vehicle system software increases since the self-diagnosis functions are generally started or evaluated via software by a microcontroller in a software-supported manner.

### SUMMARY

A method for the self-diagnosis of a vehicle system with features of the present invention and a corresponding vehicle system with features of the present invention each have the advantage that the time required for the initialization or the startup of the vehicle system can be significantly reduced. This means that the time period until the full operational readiness or availability of the vehicle system can be significantly shortened. Furthermore, the complexity of the vehicle system software can be reduced.

A feature of the present invention is to no longer perform self-diagnosis functions of the vehicle system sequentially, but to parallelize them. This leads to a significantly shorter total diagnosis time and thus to earlier availability of the functions of the vehicle system. According to an example embodiment of the present invention, for this purpose, the hardware design of at least one integrated system circuit, including additional test circuits, and the interaction with other system components, such as microcontrollers, sensors, communication interfaces, etc., can be adjusted accordingly. In addition, the individual internal self-diagnosis functions of the at least one integrated system circuit can be enhanced in a hardware-supported manner and performed and evaluated independently and without involvement of the at least one microcontroller of the vehicle system. This specifically reduces the complexity of the vehicle system software during the initialization phase or the startup phase of the vehicle system, which is preferably designed as an airbag system. In this case, the full operational readiness or availability of the airbag system can be signaled by switching off the airbag warning indicator, for example.

Example embodiments of the present invention provide a method for the self-diagnosis of a vehicle system that is supplied with energy by an on-board vehicle electrical system and comprises a control unit with at least one integrated system circuit, which comprises at least one internal energy supply, a sequence and logic controller and a safety controller, and with at least one microcontroller. In this case, after applying an on-board electrical system voltage in an initialization phase independently of an activation state of the at least one microcontroller, within the at least one integrated system circuit, at least one internal reference voltage and at least one internal system voltage for supplying the vehicle system are generated from the applied on-board electrical system voltage and hardware-supported internal self-diagnosis functions are performed. The hardware-supported internal self-diagnosis functions are started and carried out in the corresponding integrated system circuit when the at least one internal reference voltage is available. Furthermore, at least two hardware-supported internal self-diagnosis functions are processed at least partly in parallel, wherein, after the initialization phase of the at least one integrated system circuit, the at least one microcontroller has an active state and, after an internal self-diagnosis, activates and carries out at least one software-supported self-diagnosis function.

Furthermore, according to an example embodiment of the present invention, a vehicle system is provided, which is configured to perform such a method for self-diagnosis. For example, the vehicle system can comprise a control unit with at least one integrated system circuit and with at least one microcontroller. In this case, the at least one integrated system circuit can comprise at least one internal energy supply, a sequence and logic controller, and a safety controller, which can control a corresponding output stage in order to trigger at least one ignition circuit of a restraining device.

The performance and sequence of the individual self-diagnosis functions of the vehicle system is linked to several parameters or dependencies. Example embodiments of the method according to the present invention for the self-diagnosis of a vehicle system thus take into account electrical boundary conditions, such as the presence of internal system voltages, in the hardware design and in the control of the hardware-supported internal self-diagnosis functions. In addition, the start of the hardware-supported internal self-diagnosis functions is preferably triggered with the presence of the at least one internal reference voltage. Furthermore, when performing the hardware-supported internal self-diagnosis functions, interactions with other functions and/or tests can be considered and safety requirements can be met. It is thus possible to accelerate the process of the self-diagnosis of the vehicle system, to parallelize self-diagnosis functions, and to reduce the complexity of the vehicle system software.

In the present case, the control unit can be understood to mean an electronic device, such as an airbag control unit, which processes or evaluates acquired sensor signals. The control unit can comprise at least one interface, which can be designed as hardware and/or software. In a hardware design, the interfaces can, for example, also be part of the integrated system circuit, which includes a wide variety of functions of the control unit. However, it is also possible that the interfaces are separate integrated circuits or consist at least in part of discrete components. In a software design, the interfaces can be software modules, which are present, for example, on the microcontroller in addition to other software modules. It is also advantageous to have a computer program product with program code that is stored on a machine-readable carrier, such as a semiconductor memory, a hard disk memory or an optical memory and is used to carry out the evaluation when the program is executed by the microcontroller of the control unit.

Advantageous improvements to the method for the self-diagnosis of a vehicle system of the present invention and to the vehicle system of the present invention are possible by the measures and developments disclosed herein.

According to an example embodiment of the present invention, it is particularly advantageous that at least one additional test circuit and/or at least one rewritable permanent memory for carrying out the hardware-supported internal self-diagnosis functions can be implemented in the at least one integrated system circuit. In this case, the at least one rewritable permanent memory can provide electrical parameters. Alternatively, the hardware-supported internal self-diagnosis functions can also run without parameterization and without evaluation in the sequence and logic controller itself. For example, the sequence and logic controller can always carry out the individual hardware-supported internal self-diagnosis functions in the same way and then provide a corresponding “raw value” as a result to the at least one microcontroller. The at least one microcontroller can then evaluate, depending on the system variant, whether the hardware-supported internal self-diagnosis function has been completed with a positive outcome or not. In addition, the at least one test circuit can be designed and placed such that an occurrence of interactions that can be caused by influence on electrical parameters or by crosstalk can be reduced. The interactions can arise, for example, directly by influences on electrical parameters or by “crosstalk” or interferences in the case of low spatial proximities on the common silicon substrate. Embodiments of the present invention can best reduce the interactions of the hardware-supported internal self-diagnosis functions by adjusting the at least one test circuit, e.g., by optimizing the dimensioning of power sources and/or current sinks, “decoupling” current paths with diodes, or the like, in order to ensure self-diagnosis functions without any feedback. Likewise, measures that can lead to better isolation of the circuit blocks are possible in the layout of the at least one integrated system circuit. For example, optimized ground connections, optimized line runs, trenches between adjacent structures, or the like, can be implemented. Such improvements can increase the parallelization of self-diagnosis functions since there are no or reduced functional influences on the hardware-supported internal self-diagnosis functions.

In an advantageous embodiment of the method of the present invention, at least the at least two hardware-supported internal self-diagnosis functions that are processed at least partly in parallel can each comprise a digital test portion and an analog test portion. In this case, at least the digital test portions of the at least two hardware-supported internal self-diagnosis functions can be processed in parallel.

In a further, advantageous embodiment of the method of the present invention, the analog test portions of the at least two hardware-supported internal self-diagnosis functions can be processed in parallel or in a specified order depending on known feedbacks and/or safety specifications. Due to the high integration of the electrical circuits in the at least one integrated system circuit, it may happen that interactions that can also influence the hardware-supported internal self-diagnosis functions may occur between the individual hardware-supported internal self-diagnosis functions. In the implementation of such hardware-supported internal self-diagnosis functions, it is therefore considered that not all self-diagnosis functions can be started at any time or in parallel. Especially in safety-critical applications, e.g., in airbag control units, violations of the safety requirements must not occur. For example, there are interdependencies of the individual self-diagnosis functions that prevent the performance of a second hardware-supported internal self-diagnosis function if a first hardware-supported internal self-diagnosis function has not been successfully completed. These dependencies and the required control also lead to complex system software in today's systems and to a prolongation of the total time of the initial self-diagnosis process. In embodiments of the method according to the present invention for the self-diagnosis of a vehicle system, the integrated test circuits and their hardware sequence control are designed in such a way that violation of the safety requirements cannot occur. For example, a failed hardware-supported internal self-diagnosis function for a safety-critical function would automatically lead to the termination of the further hardware-supported internal self-diagnosis functions. In the best case scenario, the test circuits can be designed such that, even in the case of malfunction, they themselves do not constitute a safety risk and the hardware-supported internal self-diagnosis functions can thus continue to run with the highest possible test coverage. For example, the internal system voltages can be available at different times and/or can depend on one another. A second system voltage dependent on a first system voltage can therefore be checked only after the first system voltage has been checked and no error has been detected. Such improvements can also increase the parallelization of the hardware-supported internal self-diagnosis functions since there are no or reduced dependencies of the safety requirements of the hardware-supported internal self-diagnosis functions.

In a further, advantageous embodiment of the method of the present invention, based on the at least one internal reference voltage, at least one reference voltage and/or at least one auxiliary voltage can be generated and provided for the hardware-supported internal self-diagnosis functions. For example, the at least one auxiliary voltage can be replaced by a corresponding internal system voltage when the internal system voltage has reached its target value at a later time. This means that a multitude of self-diagnosis functions can already be performed before all internal voltages have reached their target value. For example, evaluation circuits, such as comparators, can be checked before the internal system voltage to be checked by the corresponding evaluation circuit is available.

In a further, advantageous embodiment of the method of the present invention, at least one comparator can be checked by at least one of the hardware-supported internal self-diagnosis functions, which is designed to check a switching point of the at least one comparator by changing an applied reference voltage. In this case, forwarding of an output signal of the at least one comparator can be blocked during the check. After its error-free check, the at least one comparator can be used by at least one further hardware-supported internal self-diagnosis function to check an undervoltage threshold value and/or an overvoltage threshold value of the at least one internal reference voltage and/or of the at least one internal system voltage and/or of at least one power voltage. The use of comparators enables simple and cost-effective implementation of the corresponding hardware-supported internal self-diagnosis functions.

In a further advantageous embodiment of the method of the present invention, at least one logic path of the sequence and logic controller and/or at least one logic path of the safety controller of the corresponding integrated system circuit can be checked by at least one of the hardware-supported internal self-diagnosis functions. Additionally, or alternatively, at least one PSI interface, via which sensor signals from at least one peripheral sensor unit can be received and conditioned, can be checked by at least one of the hardware-supported internal self-diagnosis functions. Furthermore, additionally, or alternatively, at least one analog interface, which can receive analog signals from external analog signal transmitters or can output analog signals to external analog signal receivers, can be checked by at least one of the hardware-supported internal self-diagnosis functions. The listed hardware-supported internal self-diagnosis functions are to be understood as examples only since the overall scope of the hardware-supported internal self-diagnosis functions can be significantly larger.

In a further, advantageous embodiment of the method of the present invention, an undervoltage threshold value and/or an overvoltage threshold value of at least one energy reserve of the vehicle system and/or an analog interface, which can receive analog signals from external analog signal transmitters or can output analog signals to external analog signal receivers, and/or a central acceleration sensor and/or a central rotation rate sensor and/or a bus interface can be checked by the at least one software-supported self-diagnosis function. The at least one software-supported self-diagnosis function is, for example, started and carried out by the system software via SPI command. This takes place when the internal system voltages are available and the microcontroller is fully supplied and has successfully completed its internal self-diagnosis.

Exemplary embodiments of the present invention are illustrated in the figures and explained in more detail in the following description. In the figures, identical reference signs refer to components or elements performing identical or similar functions.

### BRIEF DESCRIPTION OF THE DRAWINGS

FIG. 1 shows a schematic block diagram of an exemplary embodiment of a vehicle system according to the present invention.

FIG. 2 shows a schematic flow diagram of an exemplary embodiment of a method according to the present invention present for the self-diagnosis of a vehicle system of FIG. 1.

FIG. 3 shows a time sequence of several hardware-supported self-diagnosis functions and a software-supported self-diagnosis function according to the method according to the present invention for the self-diagnosis of a vehicle system of FIG. 2.

### DETAILED DESCRIPTION OF EXAMPLE EMBODIMENTS

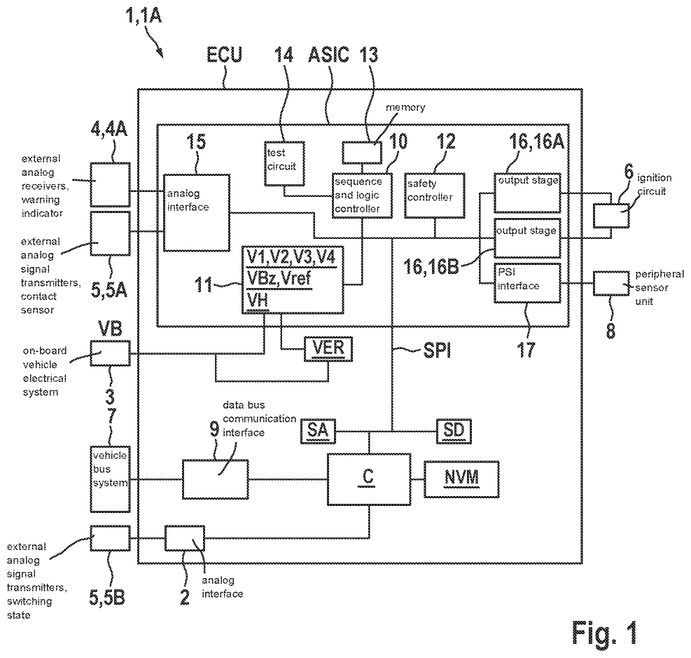

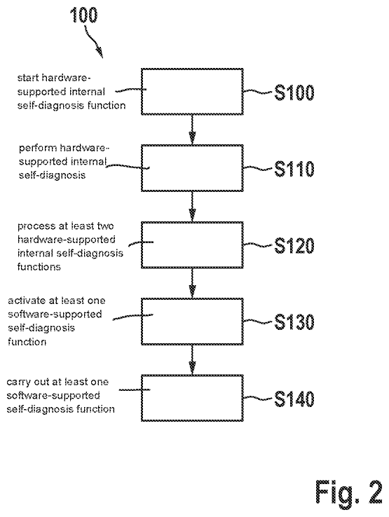

As can be seen in FIG. 1, the exemplary embodiment shown of a vehicle system 1 according to the present invention, which is configured to perform the method 100 according to the present invention shown in FIG. 2, comprises a control unit ECU with at least one integrated system circuit ASIC and at least one microcontroller μC. In the exemplary embodiment shown, the vehicle system 1 is designed as an airbag system 1A, which comprises only one integrated system circuit ASIC and only one microcontroller μC. The integrated system circuit ASIC comprises at least one internal energy supply 11, a sequence and logic controller 10, and a safety controller 12, which controls a corresponding output stage 16 in order to trigger at least one ignition circuit 6 of a restraining device not shown. As can further be seen in FIG. 1, the vehicle system 1 shown is supplied with energy by an on-board vehicle electrical system 3, which provides an on-board electrical system voltage VB.

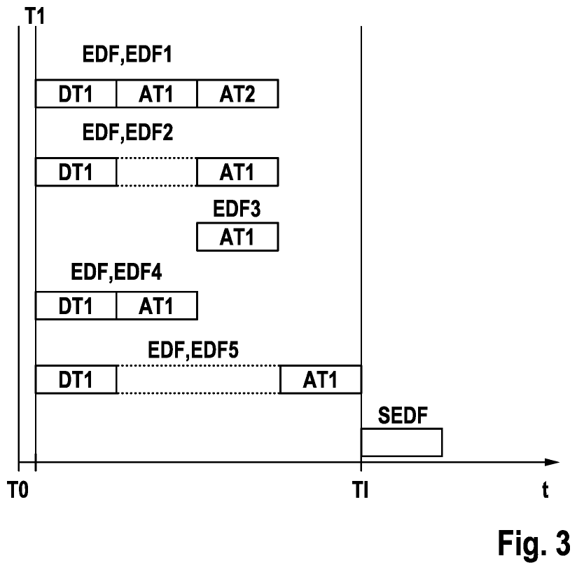

In the exemplary embodiment shown of the method 100 according to the present invention for the self-diagnosis of the vehicle system 1 shown in FIG. 1, after applying the on-board electrical system voltage VB in an initialization phase independently of an activation state of the at least one microcontroller μC, within the at least one integrated system circuit ASIC, at least one internal reference voltage VBz and at least one internal system voltage V1, V2, V3, V4 for the supply of the vehicle system 1 are generated from the applied on-board electrical system voltage VB and hardware-supported internal self-diagnosis functions EDF are performed, which are shown in FIG. 3. As can be seen in FIG. 2, the hardware-supported internal self-diagnosis functions EDF are started in the corresponding integrated system circuit ASIC in a step S100 and are performed in step S110 when the at least one internal reference voltage VBz is available. In step S120, at least two hardware-supported internal self-diagnosis functions EDF are processed at least partly in parallel, as can be seen in FIG. 3. After the initialization phase of the at least one integrated system circuit ASIC, the at least one microcontroller μC has an active state and activates, after an internal self-diagnosis, in a step S130, at least one software-supported self-diagnosis function SEDF, which is carried out in step S140.

The time sequence shown in FIG. 3 of several hardware-supported self-diagnosis functions EDF shows that, in normal operation of the vehicle, at a time T0, the on-board electrical system voltage VB is applied to the control unit ECU. The control unit ECU also comprises an internal energy reserve VER, which is charged based on the on-board electrical system voltage VB. In the case of failure of the on-board electrical system voltage VB, the internal energy reserve VER provides an energy reserve voltage in an emergency operation of the internal energy supply 11. Thus, in the exemplary embodiment shown, the internal energy supply 11 of the integrated system circuit ASIC generates four different internal system voltages V1, V2, V3, V4 from the provided on-board electrical system voltage VB in normal operation and from the provided energy reserve voltage in emergency operation. For this purpose, the internal energy supply 11 comprises several voltage regulators and/or voltage converters not shown, which generate and output the various internal system voltages V1, V2, V3, V4. In the exemplary embodiment shown, a first internal system voltage V1 has a voltage level of 6.7V and is used, for example, to supply a central acceleration sensor SA and a central rotation rate sensor SD. A second internal system voltage V2 has a voltage level of 5.0V and is used, for example, to supply a data bus communication interface 9 and an analog interface 2. A third internal system voltage V3 has a voltage level of 3.3V and is used, for example, to supply an analog interface 15 and a PSI interface 17 of the integrated system circuit ASIC and to supply the microcontroller μC. A fourth internal system voltage V4 has a voltage level of 1.29V and is used, for example, to supply a computer core of the microcontroller μC. In addition, the four internal system voltages V1, V2, V3, V4 are used to supply a rewritable permanent memory NVM (non-volatile memory), which contains program code and electrical parameters for the internal self-diagnosis of the microcontroller μC, and for the supply of the sequence and logic controller 10, the safety controller 12 and the output stage 16 of the integrated system circuit ASIC. The listed internal system voltages V1, V2, V3, V2 are to be understood as examples only; of course, more or less than four internal system voltages V1, V2, V3, V4 can also be generated and used, which can also have voltage values other than those indicated.

As can further be seen in FIG. 1, the integrated system circuit ASIC in the exemplary embodiment shown comprises a rewritable permanent memory 13, which contains electrical parameters for the hardware-supported internal self-diagnosis functions EDF and is likewise supplied by one of the four internal system voltages V1, V2, V3, V4, and several test circuits of which one test circuit 14 is shown by way of example. The test circuits 14 are likewise supplied by one of the four internal system voltages V1, V2, V3, V4. The test circuits 14 are designed and placed such that an occurrence of interactions that are caused by influence on electrical parameters or by crosstalk is reduced.

As can further be seen in FIG. 1, the internal energy supply 11 generates the at least one internal reference voltage VBz. In the exemplary embodiment shown, based on the at least one internal reference voltage VBz, a reference voltage Vref and at least one auxiliary voltage UH are generated and provided for the hardware-supported internal self-diagnosis functions EDF. The at least one auxiliary voltage UH is replaced by a corresponding internal system voltage V1, V2, V3, V4 when the internal system voltage V1, V2, V3, V4 has reached its target value at a later time.

The time sequence shown in FIG. 3 shows that the internal reference voltage UBz is available at a time T1. Within the initialization phase, the end of which is shown in FIG. 3 by a time TI, the method 100 therefore starts the hardware-supported internal self-diagnosis functions EDF in step S100 at time T1. As can further be seen in FIG. 3, the method 100 according to the present invention in the exemplary embodiment shown comprises five hardware-supported internal self-diagnosis functions EDF and one software-supported self-diagnosis function SEDF, which is started by the microcontroller μC at time TI after the end of the initialization phase.

In this case, at least one comparator is checked by at least one of the hardware-supported internal self-diagnosis functions EDF, which is performed to check a switching point of the at least one comparator by changing an applied reference voltage Uref, wherein forwarding of an output signal of the at least one comparator is blocked during the check. After its error-free check, the at least one comparator is used by at least one further hardware-supported internal self-diagnosis function EDF to check an undervoltage threshold value and/or an overvoltage threshold value of the at least one internal reference voltage VBz and/or of the at least one internal system voltage V1, V2, V3, V4 and/or of at least one power voltage. In addition, at least one logic path of the sequence and logic controller 10 and/or at least one logic path of the safety controller 12 of the integrated system circuit ASIC is checked by at least one of the hardware-supported internal self-diagnosis functions EDF. The PSI interface 17, via which sensor signals from at least one peripheral sensor unit 8 are received and conditioned, is likewise checked by at least one of the hardware-supported internal self-diagnosis functions EDF. The PSI interface 17 forwards the conditioned sensor signals of the at least one peripheral sensor unit 8 to the other components of the vehicle system 1 via an intrasystem data bus SPI, which is designed as an SPI bus. The analog interface 15, which receives analog signals from external analog signal transmitters 5, e.g., from a contact sensor 5A of a buckle, or outputs analog signals to external analog signal receivers 4, e.g., to a warning indicator 4A, is likewise checked by at least one of the hardware-supported internal self-diagnosis functions EDF.

As can further be seen in FIG. 3, a first hardware-supported internal self-diagnosis function EDF1 comprises one digital test portion DT1 and two analog test portions AT1, AT2. A second hardware-supported internal self-diagnosis function EDF2 comprises one digital test portion DT1 and one analog test portion AT1. A third hardware-supported internal self-diagnosis function EDF3 only comprises one analog test portion AT1. A fourth hardware-supported internal self-diagnosis function EDF4 comprises one digital test portion DT1 and one analog test portion AT1. A fifth hardware-supported internal self-diagnosis function EDF5 likewise comprises one digital test portion DT1 and one analog test portion AT1.

As can further be seen in FIG. 3, at least the digital test portions DT1 of the hardware-supported internal self-diagnosis functions EDF1, EDF2, EDF4, EDF5 are processed in parallel. The analog test portions AT1, AT2 of the five hardware-supported internal self-diagnosis functions EDF1, EDF2, EDF3, EDF4, EDF5 are processed in parallel or in a specified order depending on known feedbacks and/or safety specifications. Thus, the analog test portions AT1 of the first hardware-supported internal self-diagnosis function EDF1 and of the fourth hardware-supported internal self-diagnosis function EDF4 are processed in parallel after processing the digital test portions DT1 of the four hardware-supported internal self-diagnosis functions EDF1, EDF2, EDF4, EDF5. Since the second analog test portion AT2 of the first hardware-supported internal self-diagnosis function EDF1, the analog test portion AT1 of the second hardware-supported internal self-diagnosis function EDF2 and the analog test portion AT1 of the third hardware-supported internal self-diagnosis function EDF3 depend on the first analog test portion AT1 of the first hardware-supported internal self-diagnosis function EDF1, these three analog test portions AT1, AT2 are processed in parallel after the processing of the first analog test portion AT1 of the first hardware-supported internal self-diagnosis function EDF1. Since the analog test portion AT1 of the fifth hardware-supported internal self-diagnosis function EDF5 depends on the analog test portion AT1 of the third hardware-supported internal self-diagnosis function EDF3, this test portion is processed after the processing of the analog test portion AT1 of the third hardware-supported internal self-diagnosis function EDF3.

In the exemplary embodiment shown, the software-supported self-diagnosis function SEDF shown in FIG. 3 checks an undervoltage threshold value and/or an overvoltage threshold value of the energy reserve VER of the vehicle system 1. In alternative exemplary embodiments not shown, further software-supported self-diagnosis functions SEDF check the analog interface 2 and/or the central acceleration sensor SA and/or the central rotation rate sensor SD and/or the data bus communication interface 9, which is connected to a vehicle bus system 7 designed, for example, as a CAN bus. The analog interface 2 receives analog signals from external analog signal transmitters 5, such as a switching state 5B of an airbag switch not shown. In this case, the analog interface 2 can also be integrated into the microcontroller μC. In addition, the analog interface can also output analog signals to external analog signal receivers.

1-15. (canceled)

16. A method for a self-diagnosis of a vehicle system that is supplied with energy by an on-board vehicle electrical system and includes a control unit with at least one integrated system circuit, which includes at least one internal energy supply, a sequence and logic controller, and a safety controller, and with at least one microcontroller, the method comprising the following steps:
after applying an on-board electrical system voltage in an initialization phase independently of an activation state of the at least one microcontroller, within the at least one integrated system circuit, generating at least one internal reference voltage and at least one internal system voltage for supplying the vehicle system from the applied on-board electrical system voltage, and performing hardware-supported internal self-diagnosis functions, wherein the hardware-supported internal self-diagnosis functions are started and carried out in the integrated system circuit when the at least one internal reference voltage is available, wherein at least two hardware-supported internal self-diagnosis functions are processed at least partly in parallel; and
after the initialization phase of the at least one integrated system circuit, the at least one microcontroller is an active state, and, after an internal self-diagnosis, activating and carrying out at least one software-supported self-diagnosis function, by the at least one microcontroller.

17. The method according to claim 16, wherein at least one additional test circuit and at least one rewritable permanent memory for carrying out the hardware-supported internal self-diagnosis functions are implemented in the at least one integrated system circuit, and wherein the at least one rewritable permanent memory provides electrical parameters.

18. The method according to claim 17, wherein the at least one test circuit is configured and placed such that an occurrence of interactions that are caused by influence on electrical parameters or by crosstalk is reduced.

19. The method according to claim 16, wherein at least the at least two hardware-supported internal self-diagnosis functions each include a digital test portion and an analog test portion, wherein at least the digital test portions of the at least two hardware-supported internal self-diagnosis functions are processed in parallel.

20. The method according to claim 19, wherein the analog test portions of the at least two hardware-supported internal self-diagnosis functions are processed in parallel or in a specified order depending on known feedbacks and/or safety specifications.

21. The method according to claim 16, wherein, based on the at least one internal reference voltage, at least one reference voltage and/or at least one auxiliary voltage are generated and provided for the hardware-supported internal self-diagnosis functions.

22. The method according to claim 21, wherein the at least one auxiliary voltage is replaced by a corresponding internal system voltage when the internal system voltage has reached a target value at a later time.

23. The method according to claim 16, wherein at least one comparator is checked by at least one of the hardware-supported internal self-diagnosis functions, the check being performed to check a switching point of the at least one comparator by changing an applied reference voltage, wherein forwarding of an output signal of the at least one comparator is blocked during the check.

24. The method according to claim 23, wherein, after the check is error-free, the at least one comparator is used by at least one further hardware-supported internal self-diagnosis function to check an undervoltage threshold value and/or an overvoltage threshold value: (i) of the at least one internal reference voltage, and/or (ii) of the at least one internal system voltage and/or of at least one power voltage.

25. The method according to claim 16, wherein at least one logic path of the sequence and logic controller and/or at least one logic path of the safety controller of the corresponding integrated system circuit, is checked by at least one of the hardware-supported internal self-diagnosis functions.

26. The method according to claim 16, wherein at least one PSI interface, via which sensor signals from at least one peripheral sensor unit are received and conditioned, is checked by at least one of the hardware-supported internal self-diagnosis functions.

27. The method according to claim 16, wherein at least one analog interface, which receives analog signals from external analog signal transmitters or outputs analog signals to external analog signal receivers, is checked by at least one of the hardware-supported internal self-diagnosis functions.

28. The method according to claim 16, wherein an undervoltage threshold value and/or an overvoltage threshold value of at least one energy reserve of: (i) the vehicle system, and/or (ii) an analog interface, which receives analog signals from external analog signal transmitters or outputs analog signals to external analog signal receivers, and/or (iii) a central acceleration sensor, and/or (iv) a central rotation rate sensor, and/or (v) a data bus communication interface, is checked by the at least one software self-diagnosis function.

29. A vehicle system that is supplied with energy by an on-board vehicle electrical system and comprises a control unit with at least one integrated system circuit, which includes at least one internal energy supply, a sequence and logic controller, and a safety controller, and with at least one microcontroller, the vehicle system configured to:
after applying an on-board electrical system voltage in an initialization phase independently of an activation state of the at least one microcontroller, within the at least one integrated system circuit, generate at least one internal reference voltage and at least one internal system voltage for supplying the vehicle system from the applied on-board electrical system voltage, and perform hardware-supported internal self-diagnosis functions, wherein the hardware-supported internal self-diagnosis functions are started and carried out in the integrated system circuit when the at least one internal reference voltage is available, wherein at least two hardware-supported internal self-diagnosis functions are processed at least partly in parallel; and
after the initialization phase of the at least one integrated system circuit, the at least one microcontroller is an active state, and, after an internal self-diagnosis, activate and carry out at least one software-supported self-diagnosis function, by the at least one microcontroller.

30. A vehicle system, comprising:
a control unit including at least one integrated system circuit, which includes at least one internal energy supply, a sequence and logic controller, and a safety controller, which controls a corresponding output stage to trigger at least one ignition circuit of a restraining device, and the control unit further including at least one microcontroller.
